(19) United States
(12) Patent Application Publication
(10) Pub. No.: US 2009/0065350 A1
(43) Pub. Date: Mar. 12, 2009

(54) FILTERED CATHODIC ARC DEPOSITION WITH ION-SPECIES-SELECTIVE BIAS

(75) Inventor: Andre Anders, El Cerrito, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 12/205,721

(22) Filed: Sep. 5, 2008

Related U.S. Application Data
(60) Provisional application No. 60/970,855, filed on Sep. 7, 2007.

(51) Int. Cl. C23C 14/28

(52) U.S. Cl. 204/192.12; 204/298.02; 204/298.09

(57) ABSTRACT

A dual-cathode arc plasma source is combined with a computer-controlled bias amplifier to synchronize substrate bias with the pulsed production of plasma. Accordingly, bias can be applied in a material-selective way. The principle has been applied to the synthesis metal-doped diamond-like carbon films, where the bias was applied and adjusted when the carbon plasma was condensing, and the substrate was at ground when the metal was incorporated. In doing so, excessive sputtering by too-energetic metal ions can be avoided while the sp³/sp² ratio can be adjusted. It is shown that the resistivity of the film can be tuned by this species-selective bias. The principle can be extended to multiple-material plasma sources and complex materials.

### CLAIM OF PRIORITY

This application claims benefit to the following U.S. Provisional Patent Application:

U.S. Provisional Patent Application No. 60/970,855 entitled “FILTERED CATHODIC ARC DEPOSITION WITH ION-SPECIES-SELECTIVE BIAS”, by André Anders, filed Sep. 7, 2007, Attorney Docket No. NANO-01095US0.

This invention was made with government support under Contract No. DE-AC03-76SF00098/DE-AC02-05CH11231 awarded by the U.S. Department of Energy. The government has certain rights in the invention.

### TECHNICAL FIELD

The present invention relates generally to film deposition.

### BACKGROUND

Substrate bias is a tool for controlling the energy of ions in plasma-based thin film growth. A space charge sheath forms between a substrate surface and the plasma bulk. Typically, the substrate bias is negative such that positive ions are extracted from the sheath-plasma edge and accelerated before they impact the substrate surface. Provided the sheath is much thinner than the mean free path between collisions, when traveling through the sheath ions gain the kinetic energy

ΔEₖᵢₙ=QeΔVₛₕₑₐₜₕ

where Q is the ion charge state number, e is the elementary charge, and ΔVₛₕₑₐₜₕ is the voltage drop between plasma sheath edge and the substrate surface. By controlling the energy of ions, film properties such as density and stress are affected and can be tuned and optimized for the desired application. In the case of crystalline films, preferred orientation and texture can be influenced as well.

Highly ionized plasmas are of interest to some coating processes because bias techniques can be effective, acting on ions but not on the neutral atoms. Examples of highly ionized plasmas are cathodic arc and high power impulse magnetron sputtering (HIPIMS) plasmas.

Various forms of bias are known such as direct current (DC) bias, pulsed DC bias, radio frequency (RF) bias, etc. The bias acts on all ion species that enter the sheath from the plasma sheath edge. This characteristic of bias can be undesirable when ions of very different masses are involved because their sputter yields are different, even when their final energy at arrival on the substrate surface is the same. The issue can be aggravated when the heavier ion has a higher charge state. In this case, the energy is enhanced proportional to the charge state, and therefore the sputter yield is much higher by the combination of greater mass and higher energy. An excessive sputter yield can be detrimental to making the desired coating composed of light and heavy atoms. Therefore, it can be desirable to tune the bias in such a way as to adjust the value according to the species that are arriving.

### SUMMARY

A pulsed cathodic arc plasma source having two “triggerless” cathodes in a common anode body allows materials-selective bias by synchronizing the bias amplitude with the presence of the plasma of a specified material. The cathodes can comprise, in an embodiment, carbon and molybdenum. The bias voltage can be systematically adjusted for carbon only to obtain a target electrical resistivity of the growing film, while the metal deposition is not affect. Methods in accordance with the present invention using arc plasma sources with multiple cathodes and selective application of bias can allow a great variety of films and multilayers of mixed and complex composition to be formed.

### BRIEF DESCRIPTION OF THE FIGURES

FIG. 1 is a schematic of an embodiment of a system in accordance with the present invention using a dual-cathode cathodic arc plasma source and selective, synchronized initiation of arc pulses and bias pulses.

FIG. 2 illustrates a cathodic arc plasma source with two cathodes in a water-cooled anode body.

FIG. 3 is a flowchart for an embodiment of a method of forming a film in accordance with the present invention.

FIG. 4 is a plot of resistivity of ta-C:Mo films with the pulsed bias acting only on carbon ions.

FIG. 5 is a schematic of an alternative embodiment of a system in accordance with the present invention using a dual cathodic arc plasma sources and selective, synchronized initiation of arc pulses and bias pulses.

### DETAILED DESCRIPTION

Metal-doped tetrahedral amorphous carbon films, usually designated as ta-C:Me, can be formed by filtered cathodic arc deposition. Cathodic arc deposition techniques generate an electrical arc that blasts ions from a cathode. Because ions are blasted from the surface of the cathode ballistically, it is common for not only single atoms, but larger clusters of atoms to be ejected. Cathodic arc deposition techniques use a filter to remove atom clusters from the beam before deposition.

In order to produce a film rich in tetrahedral (i.e., diamond) bonding (also referred to herein as sp³ bonding), carbon ions produced by a cathodic arc preferably have an energy of about 100-120 eV. Referring to Table 1, average ion charge state, particle charge state fractions, and the most likely “natural” kinetic energy of ions are shown for cathodic arc plasmas for a selection of elements. Because the “natural” kinetic energy of carbon ions is about 19 eV, negative bias of typically about 100 V is applied to produce a diamond-like film. If metal ions are produced by a cathodic arc, their most likely charge state is typically about 2 or 3 and their most likely “natural” energy typically exceeds 50 eV. When a negative bias of 100 V acts on the metal ions, their total kinetic energy can approach the range of 300-500 eV, which can cause severe sputtering. Moreover, the energetic impact of the metal ions on the surface can promote relaxation of sp³ bonds to sp² bonds, thereby reducing the “diamond-likeness” of the film.

TABLE 1

| Material | Q | f₁ | f₂ | f₃ | f₄ | f₅ | f₆ | Eₖᵢₙ (eV) |
|---|---|---|---|---|---|---|---|---|
| C | 1.00 | 100 | | | | | | 19 |
| Ti | 2.03 | 11 | 75 | 14 | | | | 59 |
| Cr | 2.09 | 10 | 68 | 21 | 1 | | | 72 |
| Mo | 3.06 | 2 | 21 | 49 | 25 | 3 | | 149 |
| W | 3.07 | 2 | 23 | 43 | 26 | 5 | 1 | 117 |

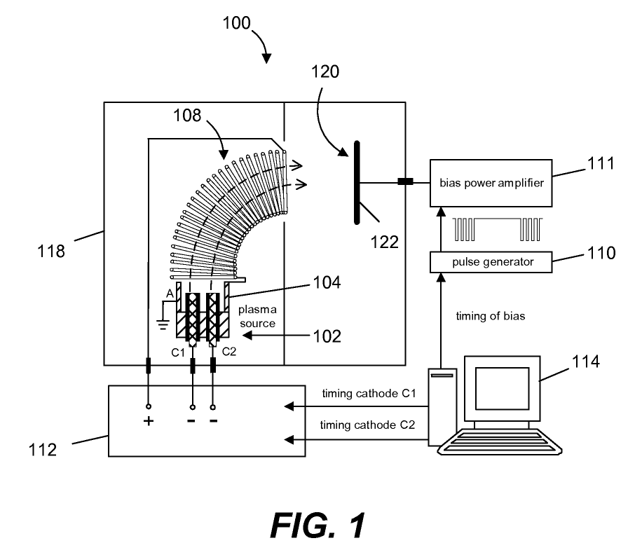

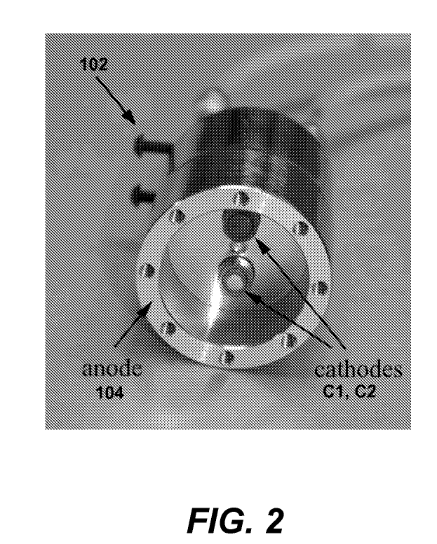

Referring to FIG. 1, embodiments of systems 100 for forming films on a substrate 120 in accordance with the present invention can comprise a cathodic arc plasma source 102 including a first cathode C1 formed of carbon placed in close vicinity to a second cathode C2 formed of a metal inside a common anode body 104. A cathodic arc plasma source 102 is further shown in FIG. 2. The anode body 104 can be cooled to allow operation of the cathodic arc plasma source 102 with, in one implementation, pulses up to about 2 kA with duration of typically 1 ms, at a repetition rate of up to 10 pulses per second. At such operating parameters, the duty cycle is low (1% or less) and the average current and power are about 10 A and 200 W, respectively. Cathodic arc pulses can be initiated by applying an open-circuit voltage (typically 600 V), for example by an arc power supply 112, to the selected cathode C1,C2. Since no trigger electrode is required, the system can be said to employ “triggerless” triggering.

The dual-cathode cathodic arc plasma source 102 can be used to inject streaming cathodic arc plasma into a plasma filter 108, such as an open 90° filter, to remove unwanted macro-particles. A macro-particle “firewall” 118 within the chamber physically blocks particles emanating from the arc source and filter region. The cathodic arc plasma generated by the dual-cathode cathodic arc plasma source 102 can be selectively synchronized with a species-selective bias applied to an electrode 122 associated with the substrate 120 by a pulse generator 110, which signal is amplified by a bias power amplifier 111, to reduce excessive metal ion energy while having desirable carbon ion energy. Thus, for example, bias pulses can be applied when carbon ions arrive at the substrate 120 to have a desirable energy of about 100-120 eV to optimize the sp³ content of film. The bias pulses can be reduced or omitted when metal ions arrive at the substrate 120, thereby reducing sputtering and sp³ bond relaxation. In an embodiment, synchronization can be controlled by a microcontroller such as an application specific integrated circuit (ASIC), or alternatively a general computing device 114 (e.g., a personal computer (PC)). Synchronization sequences can be defined by hardware and/or software.

The plasmas paths inside the plasma filter 108 and at the plasma filter exit are offset because the injection points of plasma from the two cathodes C1,C2 are slightly different. If deposition occurs close to the filter exit without repositioning the substrate 120 onto which the film is deposited, two center regions of coatings are produced offset with respect to each other, with each center corresponding to one cathode material. The offset can be utilized if a combinatorial approach to materials research is desired, or reduced by increasing a distance from the filter exit to the substrate 120 (for example to more than 10 cm) and/or applying substrate motion.

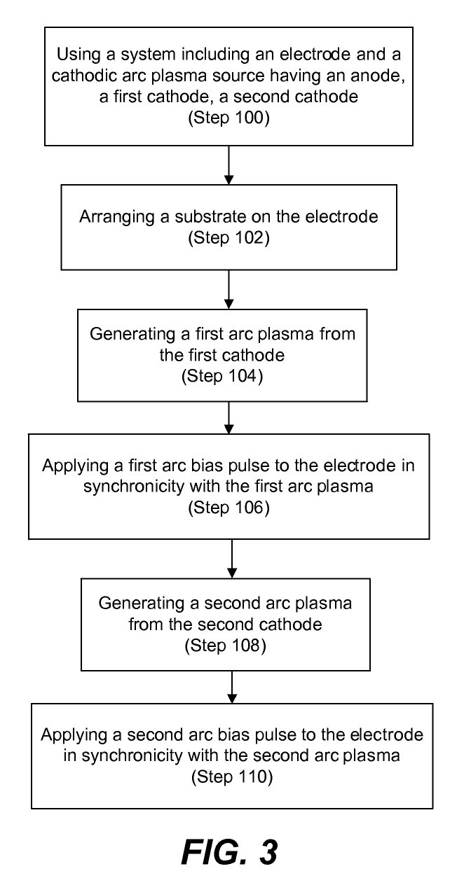

Referring to FIG. 3, an embodiment of a method in accordance with the present invention for forming a film on a substrate can comprise using a system including an electrode and a cathodic arc plasma source having an anode, a first cathode, and a second cathode (Step 100). A substrate is arranged on the electrode (Step 102) and a first arc plasma is generated from the first cathode (Step 104). A first bias is applied to the electrode to generate a desired energy of the ions in the first arc plasma (Step 106). A controller synchronizes the first bias and the first arc plasma, so that the appropriate bias is applied to the ions present in the arc plasma. A second arc plasma is generated from the second cathode (Step 108), and a second bias is applied to the electrode to generate a desired energy of the ions in the second arc plasma (Step 110). The controller synchronizes the second bias and the second arc plasma, so that the appropriate bias is applied to the ions present in the second arc plasma. A complex film can be built on the surface by sequentially performing the synchronized application of bias pulses and plasma generation, according to a sequence defined by a recipe, for example.

Cathodic arc deposition was demonstrated using an experimental setup resembling the embodiment of FIG. 1. The experimental setup included a filtered dual-cathode cathodic arc system comprising a cathodic arc plasma source including a first cathode formed of carbon, a second cathode formed of molybdenum and a 90° open filter. Cathodic arc deposition was performed using the setup to produce a ta-C:Mo film on a substrate. An arc power supply was used to pulse the arc plasma between the two cathodes and a pulse generator connected with a bias power amplifier applied a bias to the substrate. A PC equipped with a National Instruments® virtual instrument with LabView® software was programmed to synchronize the bias pulses and arc pulses. The synchronization allowed writing recipes for the film composition and structure in which the number of arc pulses, their sequence, and the amplitude of bias were freely adjustable. The experimental setup allowed formation of a ta-C:Mo film where the carbon ions “saw” bias whereas the molybdenum ions arrived at an unbiased (grounded) substrate. In this sense, “species-selective” biasing was realized.

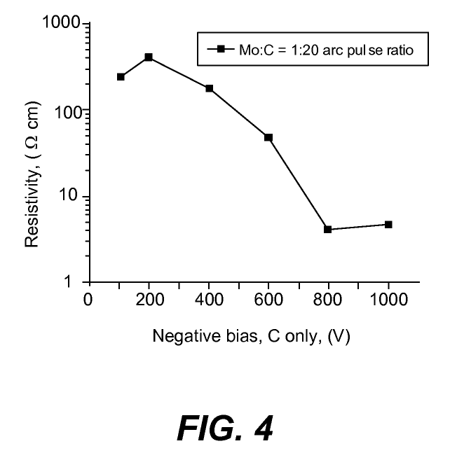

FIG. 4 is a plot of resistivity of ta-C:Mo films with the pulsed bias acting only on the carbon ions (pulsed bias: 2 μs on and 6 μs off, for the duration of the presence of carbon plasma). The substrate was at ground when molybdenum plasma arrived. The molybdenum to carbon arc pulse ratio was kept constant at 1:20. The amplitude of the bias for carbon plasma was varied with the goal to tune the sp³/sp² ratio and thereby adjust the related optical and electrical properties, particularly the resistivity, while keeping the metal content at a constant level. Every 21^{st} pulse was a metal pulse, and the metal was deposited with the substrate at ground. As can be seen, the resistivity was reduced as bias was increased to a level sufficient to provide desirable energy to the carbon ions, thereby forming a film rich in sp³ bonding.

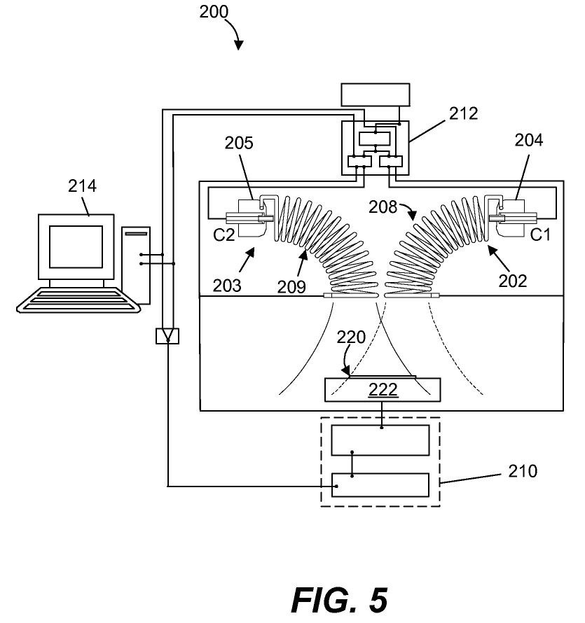

Further embodiments of systems for forming films on a substrate in accordance with the present invention can include additional cathodes, thereby increasing the versatility and possibilities even further. In still further embodiments, additional anodes can be employed, so that multiple cathodic plasma arc sources 202,203 can be used. Such a system 200 is shown in FIG. 5. As shown, the system 200 includes two cathodes (C1,C2) with each cathode arranged in an anode body 204,205 and directed toward the substrate 220 through a corresponding filter 208,209. Cathodic arc pulses can be initiated by applying an open-circuit voltage, for example by an arc power supply 212, to the selected cathode C1,C2. As above, the application of bias pulses to an electrode 222 by a pulse generator 210 is controlled by a PC 214 capable of sequencing or otherwise controlling the application of bias power to ions in the sheath.

In still further embodiments, the background gas can be yet another source of material: the cathodic arc plasma sources can be used in reactive mode, producing compound films but utilizing the presence of reactive gases in the chamber (oxygen for oxides, nitrogen for nitrides, etc.). With these extensions, it is anticipated that a great variety of complex systems can be produced. For example, a system having three cathodes, an yttrium (Y) cathode, a barium (Ba) cathode, and a copper (Cu) cathode, operating in an oxygen background gas can be employed to synthesize YBCO high-T, superconducting films. Other examples of complex films that can be produced with embodiments of systems and methods in accordance with the present invention include transparent magnetic semiconductors such as ZnO:Cr, or transparent electronics based on ZnO:M, where “M” is a dopant that produces n-type or p-type conductivity and films including ternary oxides that show colossal magnetoresistance such as Nd_{0.7}Sr_{0.3}MnO₃, or multiferroics such as BiFeO₃, Bi₂FeCrO₆, BiCrO₃, LaTiO₃, and SrTiO₃.

Embodiments of systems for forming films on a substrate have been described herein as having bias pulses and cathodic arc plasma generation synchronized to enable sequentially deposition of materials to synthesize films with mixed material content or to deposit multilayers, as determined by the recipe of the process. In still further embodiment, systems and methods in accordance with the present invention can include simultaneous cathode operation using either a single power supply with a low-ohm distributing circuit, or by using two individual power supplies, each dedicated to a single cathode. Such simultaneous operation may be beneficial when the components need to react with each other rather than with the residual gas of the background vacuum.

1. A system for forming a film comprising:
a cathodic arc plasma source including:
an anode body,
a first cathode disposed within the anode body, and
a second cathode disposed within the anode body, and
a power supply selectively connectable with the first cathode and the second cathode to generate a plasma;
an electrode on which a substrate is arrangeable;
a pulse generator connected with the electrode to apply a bias pulse;
a plasma filter to remove unwanted particles generated at the first cathode and the second cathode; and
a controller adapted to synchronize the power supply and the pulse generator.

2. The system of claim 1, wherein:
the first cathode comprises carbon;
the second cathode comprises molybdenum; and
the plasma filter is a 90° filter.

3. The system of claim 1, further comprising a computer readable medium including instructions to synchronize a bias pulse applied by the pulse generator and an arc pulse applied by the power supply.

4. The system of claim 1, wherein:
the cathodic arc plasma source is arranged in a chamber; and
one or more reactive gases are present in the chamber.

5. The system of claim 4, wherein
the cathodic arc plasma source further includes a third cathode disposed within the anode body;
the power supply is selectively connectable with the third electrode;
the first cathode comprises yttrium;
the second cathode comprises barium;
the third cathode comprises copper; and
the one or more reactive gases comprises oxygen.

6. The system of claim 1, wherein the anode body is actively cooled.

7. A system for forming a film comprising:
a cathodic arc plasma source including:
a first anode body,
a first cathode disposed within the first anode body,
a second anode body, and
a second cathode disposed within the second anode body, and
a power supply selectively connectable with the first cathode and the second cathode to generate a plasma;
an electrode on which a substrate is arrangeable;
a pulse generator connected with the electrode to apply a bias pulse;
a first plasma filter to remove unwanted particles generated at the first cathode;
a second plasma filter to remove unwanted particles generated at the second cathode; and
a controller adapted to synchronize the power supply and the pulse generator

8. The system of claim 7, wherein:
the first cathode comprises carbon;
the second cathode comprises molybdenum;
the first plasma filter is a 90° filter; and
the second plasma filter is a 90° filter.

9. The system of claim 7, further comprising a computer readable medium including instructions to synchronize a bias pulse applied by the pulse generator and an arc pulse applied by the power supply.

10. The system of claim 7, wherein:
the cathodic arc plasma source is arranged in a chamber; and
one or more reactive gases are present in the chamber.

11. The system of claim 10, wherein
the cathodic arc plasma source further includes a third anode body and a third cathode disposed within the third anode body;
the power supply is selectively connectable with the third electrode;
the first cathode comprises yttrium;
the second cathode comprises barium;
the third cathode comprises copper; and
the one or more reactive gases comprises oxygen; and
further comprising a third plasma filter to remove unwanted particles generated at the third cathode.

12. The system of claim 7, wherein the anode body is actively cooled.

13. A method for forming a complex film comprising:
using a system including a cathodic arc plasma source having an anode body, a first cathode disposed within the anode body, a second cathode disposed within the anode body, and an electrode;
arranging a substrate on the electrode;
generating a first arc plasma from the first cathode; and
applying a first bias to the electrode synchronized with the step of generating a first arc plasma so that ions from the first arc plasma are urged toward the substrate.

14. The method of claim 13, wherein individual ions from the first arc plasma have different energy; and further comprising:
filtering the ions so that ions contact the substrate with energy within a desired range.

15. The method of claim 13, further comprising:
generating a second arc plasma from the second cathode;
applying a second bias to the electrode synchronized with the step of generating a second arc plasma so that ions from the second arc plasma are urged toward the substrate.

16. The method of claim 15, wherein individual ions from the second arc plasma have different energy; and further comprising:
filtering the ions so that ions contact the substrate with energy within a desired range.

17. The method of claim 16, wherein the steps of generating a first arc plasma and applying a first bias to the electrode are alternated with the steps of generating a second arc plasma and applying a second bias to the electrode to form a doped film.

18. A method for forming a complex film comprising:
using a system including a cathodic arc plasma source having a first anode body, a first cathode disposed within the first anode body, a second anode body, a second cathode disposed within the second anode body, and an electrode;
arranging a substrate on the electrode;
generating a first arc plasma from the first cathode; and
applying a first bias to the electrode synchronized with the step of generating a first arc plasma so that ions from the first arc plasma are urged toward the substrate.

19. The method of claim 18, wherein individual ions from the first arc plasma have different energy; and further comprising:
filtering the ions so that ions contact the substrate with energy within a desired range.

20. The method of claim 19, further comprising:
generating a second arc plasma from the second cathode;
applying a second bias to the electrode synchronized with the step of generating a second arc plasma so that ions from the second arc plasma are urged toward the substrate; and
filtering the ions so that ions contact the substrate with energy within a desired range.
